(19) United States
(12) Patent Application Publication
(10) Pub. No.: US 2014/0175590 A1
(43) Pub. Date: Jun. 26, 2014

(54) GETTER STRUCTURE FOR WAFER LEVEL VACUUM PACKAGED DEVICE

(71) Applicant: RAYTHEON COMPANY, Waltham, MA (US)

(72) Inventors: Roland Gooch, Dallas, TX (US); Adam M. Kennedy, Santa Barbara, CA (US); Stephen H. Black, Buellton, CA (US); Thomas Allan Kocian, Dallas, TX (US); Buu Diep, Murphy, TX (US)

(73) Assignee: Raytheon Company, Waltham, MA (US)

(21) Appl. No.: 13/721,545

(22) Filed: Dec. 20, 2012

(51) Int. Cl. H01L 31/0203

(52) U.S. Cl. CPC H01L 31/0203
USPC 257/433; 428/161; 29/527.1

(57) ABSTRACT

A wafer level vacuum packaged (WLVP) device having a first substrate having an array of detectors and a second substrate bonded to the first substrate having a plurality of protrusions and a plurality of getter material members projecting outwardly from a sidewall of the protrusions members are disposed at oblique angles to the sidewalls and have ends extending into gaps between the protrusions. The device is formed by: forming protrusions into a surface of a substrate; and depositing getter material by physical vapor deposition from an evaporating source of the getter material at an oblique angle to the sidewalls, atoms of the getter material initially forming nucleation sites on the sidewalls with subsequent atoms attaching to the nucleation sites and shadowing area surrounding each nucleation site, the getter material thereby growing into structures towards the evaporating source.

### TECHNICAL FIELD

This disclosure relates generally to getter structures and more particularly to getter structures for wafer level vacuum packaged (WLVP) devices.

### BACKGROUND

As is known in the art, in order to maintain a high degree of vacuum in a sealed vacuum container, such as for example in a so called a Dewar assembly, a getter has been used to trap gas molecules that slowly leak through the Dewar assembly seal or seep through the container material. Widely used getter materials include titanium, molybdenum and tantalum, which permanently capture various gas molecules such as oxygen, hydrogen, nitrogen, methane, carbon monoxide and carbon dioxide that are typically found in an outgassed vacuum-sealed Dewar assembly. The getter materials react with these gases to firm oxides, carbides, hydrides and nitrides which are stable at room temperature. Therefore, the reactions are irreversible and do not involve the risk of future gas release.

Trapping of residual gas molecules in a Dewar assembly has been achieved by conventional externally fired getters, an example of which is described in U.S. Pat. No. 5,111,049, inventors Romano et al. A getter material such as a porous mixture of titanium and molybdenum powders is placed within an Alloy 42 container, which is welded onto a tube protruding from the Dewar body. The getter material is activated by applying heat to the getter container at about 800 degrees C. for about 10 minutes. However, the externally fired getter is large and bulky, and must be fabricated external to the Dewar body. To maintain a high degree of vacuum in a Dewar assembly that contains a modern planar Infrared (IR) detector array, which is typically rectangular with dimensions generally on the order of 0.5 to 2 cm, the use of an externally fired getter greatly increases the volume and weight of the assembly. Moreover, the getter material must be located away from the IR detector array, and external cooling must be applied to the Dewar body to prevent thermal damage to the detector array and other Dewar assembly components caused by the heat supplied to the getter. The mechanical complexity of the getter assembly and the need for an external cooler for the IR detector array increases the cost of the IR detector.

A process for fabricating the vacuum-sealed Dewar assembly is described in U.S. Pat. No. 5,433,639. However, since the surface area of the deposited thin film getter is small, the amount of gas that can be removed by the getter is limited. Because the IR detectors preferably have a large fill factor which is the ratio of the detector surface area to the total substrate surface area to increase the effectiveness of detection, the percentage of surface area upon which the getter material can be deposited is therefore relatively small.

As is also known in the art, a conventional uncooled IR detector array is housed in a vacuum-sealed Dewar assembly with a planar IR window, usually made of germanium and coated with a surface coating to improve its IR transmittance. IR radiation passes through the window and strikes the detector pixels in the array. Uncooled IR detectors are typically silicon or Vanadium Oxide microbolometers (SMBs), which are temperature sensors that detect IR radiation by heat sensing. While it is desirable that the detector pixels occupy as much surface area of the substrate as possible, it is impractical to have a detector array with a 100% fill factor because the array would no longer comprise pixels. Moreover, the gaps between pixels provide spacing for conductive strip lines or other circuit elements that may be fabricated on the same substrate surface. Many uncooled IR detector arrays have fill factors in the range of about 60-80%, When the fill factor is less than 100%, some IR radiation strikes the gaps between the pixels and is-undetected, thereby reducing the detection efficiency.

As is also known in the art, integrating a getter into a wafer level vacuum packaged (WLVP) device that requires a large area optical window is very limited in available area to place the getter. In a wafer level packaged device the getter is usually vacuum deposited by evaporation or sputtering the getter material onto the device lid. In an optical device, such as an IR imaging Focal Plane Array (FPA), the window occupies most of the available area onto which the getter would be deposited.

One technique is described in U.S. Pat. No. 5,701,008. As described therein, an increase in the surface area of getter is achieved by etching a multitude of trenches to form column-like protrusions in the cap wafer surface where the getter is to be placed. The getter is deposited conformally on the convoluted surface, thereby increasing its surface area by adding a third dimension to the two-dimensional surface area. The getter is deposited conformally by evaporation or sputtering onto the walls of the column-like protrusions as well as the planar horizontal surfaces. Other attempts involve methods to roughen the surface to increase the area slightly before depositing a getter.

### SUMMARY

In accordance with the present disclosure, a getter structure is provided having: a substrate having a protrusion formed in a surface thereof; and a plurality of members projecting outwardly from a sidewall of the protrusion.

In one embodiment, a getter structure is provided having a substrate having a trench formed in a surface thereof to form a protrusion on the surface; and a plurality of members projecting outwardly from a sidewall of the protrusion, such members being disposed at oblique angles to said sidewall.

In one embodiment, a wafer level vacuum packaged (WLVP) device is provided having: a first substrate having an array of detectors thereon; a second substrate vacuum bonded to the first substrate having: a protrusion and a plurality of members projecting outwardly from a sidewall of the protrusion.

In one embodiment, the members are elongated members.

In one embodiment, a method is provided for forming a getter structure. The method includes: forming a protrusion on a surface of a substrate; and depositing getter material by deposition from an evaporating source of the getter material, atoms of the getter material initially forming nucleation sites on the sidewalls with subsequent atoms attaching to the nucleation sites and shadowing area surrounding each nucleation site, the getter material thereby growing into a plurality of structures towards the evaporating source.

With such an arrangement, the use of the etched trenches form narrow column-like protrusions and deposit of the getter material by physical vapor deposition (PVD) evaporation at a sufficient distance that the arriving evaporant coats the walls of the trenches (i.e., on the sidewalls of the column-like protrusions) at an oblique angle. The film will initially form nucleation sites on the walls of the trenches. Subsequent atoms will attach to these sites and shadow the immediate area surrounding each site. The film growth will form noodles growing into the direction of the evaporating source. The deposition will be discontinuous and will have a very large effective surface area many times the geometrical area of the column-like protrusion surfaces.

This disclosure provides a method of increasing the effective getter area over the available geometrical area.

Metals deposited by vacuum evaporation onto a surface at a very oblique angle (grazing angle, less than 2 or 3 degrees) will initially nucleate in points on the surface. Further deposition will grow from these points into the depositing direction. As each grain grows, it shadows the area immediately behind it, forcing the growth to form members, growing into the direction of the arriving atoms. If the trench structure described in U.S. Pat. No. 5,701,008 is etched into a Si lid wafer using very narrow trenches, a getter material Deposited˜vertically (approximately 90 degrees to the plane of the lid wafer) will form such members on the walls of the trenches, as well as conformally coat the top surface. The resulting surface area of the deposit will be greater than the geometrical area of the surfaces of the trenches plus the remaining area of the top surface.

The details of one or more embodiments of the disclosure are set forth in the accompanying drawings and the description below. Other features, objects, and advantages of the disclosure will be apparent from the description and drawings, and from the claims.

### DESCRIPTION OF DRAWINGS

FIG. 1 is a simplified cutaway perspective view of a Dewar assembly for an IR detector array in accordance with the disclosure;

FIG. 2 is a simplified plan view of the IR detector array of used in the assembly of FIG. 1;

FIG. 3a is a perspective view of the IR window of the assembly of FIG. 1 with a getter structure according to the disclosure;

FIG. 3b is an enlarged perspective view of a portion of the getter structure of FIG. 3a, such view showing a portion of trench etched into a surface of the getter structure to form column-like protrusions of FIG. 3a without showing the getter material members on the protrusions; and

FIG. 4 is a sectional view of the IR detector Dewar assembly of FIG. 1;

FIG. 5 is a side view of the getter structure of FIG. 3a, such view showing the trenches formed in the getter structure of FIG. 3a prior to formation of the getter material members by physical vapor deposition (PVD) evaporation on sidewalls of the trenches and aligned with a source of getter material;

FIG. 5A is an enlarged cross section view of a portion of the getter structure of FIG. 5 after formation of the getter material members by physical vapor deposition on sidewalls of the trenches.

Like reference symbols in the various drawings indicate like elements.

### DETAILED DESCRIPTION

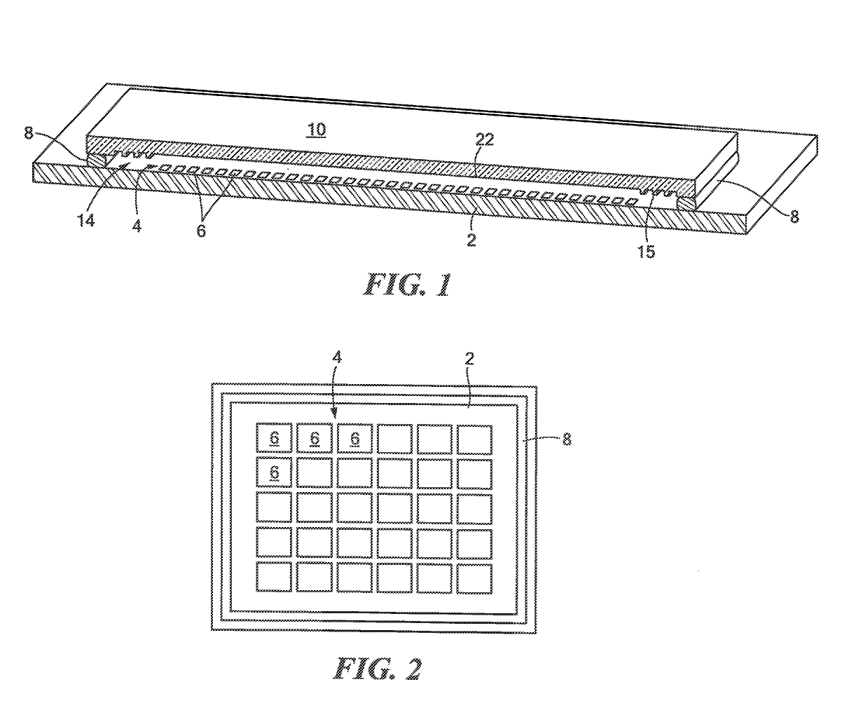

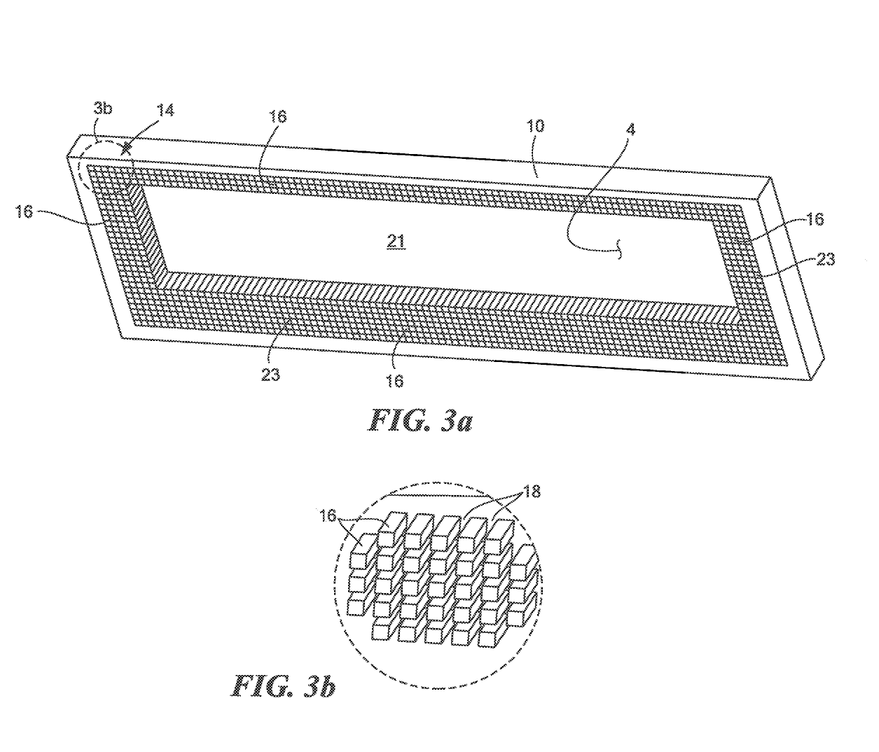

Referring now to FIGS. 1 and 2, a Dewar assembly is shown having a readout integrated circuit (ROIC) substrate 2 of a semiconductor material, preferably silicon. An IR detector array 4 is positioned on the substrate 2 and includes a plurality of individual detector elements, also called pixels, 6. Although FIG. 2 shows only a 5×6 rectangular array of detector pixels 6, it is understood that a typical IR integrated circuit generally includes a planar IR detector array with up to several hundred by several hundred pixels 6. In most commercial applications, IR detectors are usually uncooled and detect the intensity of IR radiation by sensing increases in temperature which result from the heat imparted to the detectors by the IR radiation. A typical example of an uncooled IR detector is a vanadium oxide (VOx) microbolometer (MB), in which a plurality of individual detectors are usually formed in an array on the ROIC substrate 2 by conventional semiconductor manufacturing processes. The MB array detects IR radiation by sensing the IR-generated heat, and is also called a focal plane array (FPA) or a sensor chip assembly (SCA). The substrate 2 is an integrated circuit used to process the signal produced by the bolometers. In this case the bolometer is a microbridge resistor that changes its resistance when it is heated up. The incoming radiation causes a change in the temperature of the microbridge. Although other semiconductor materials such as Si may be used, VOx is a commonly available and cost effective material that is used in most commercial IR detection applications.

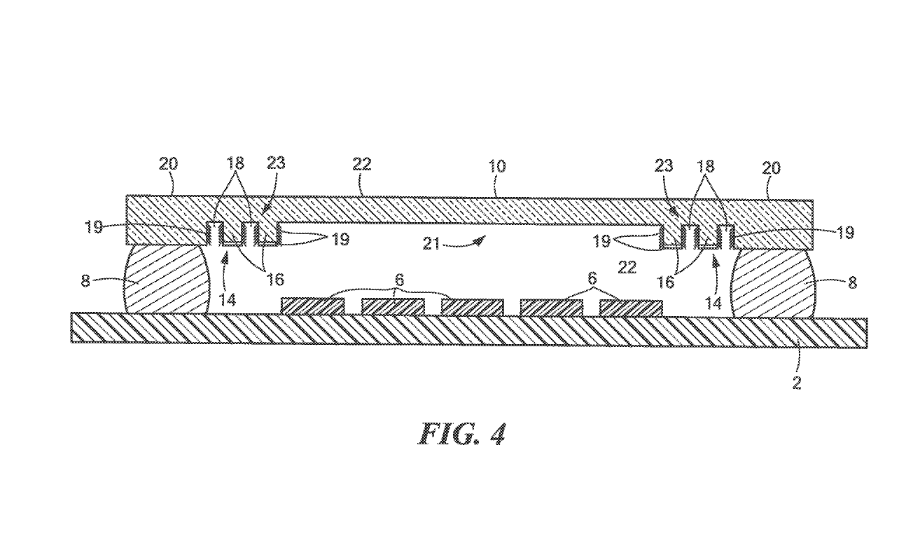

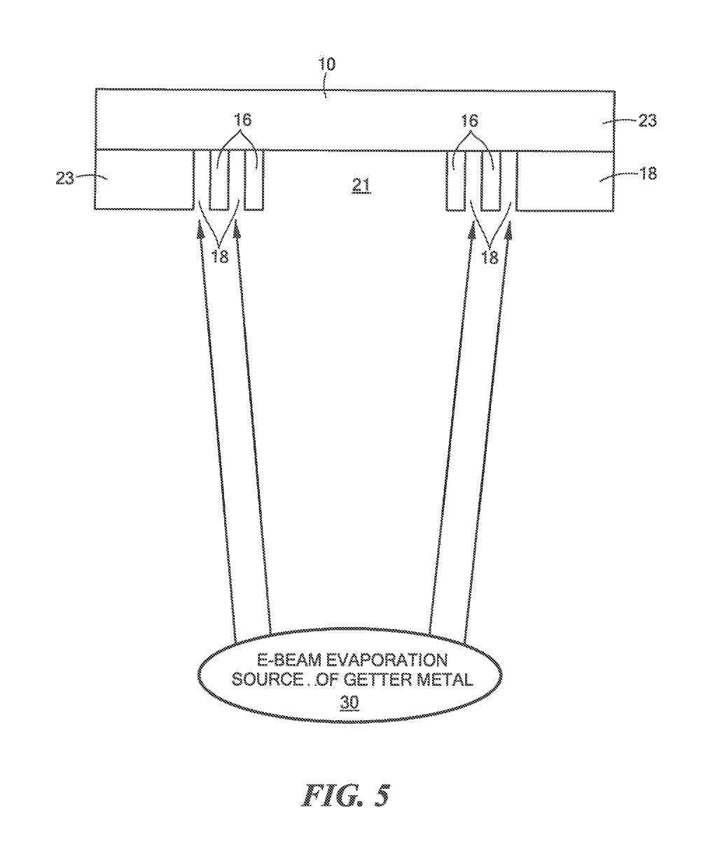

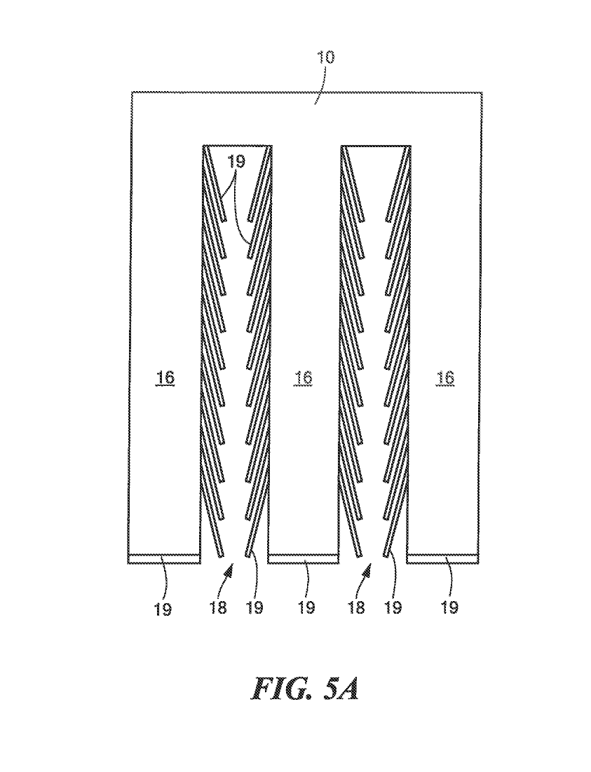

The vacuum-sealed Dewar assembly includes a seal 8 (FIG. 4) surrounding the IR detector array to seal off the detector array from the atmosphere. The seal 8 can be, for example, an indium, gold-tin, or lead solder, with the height of the seal precisely controlled when it is deposited on the substrate 2 or preferably wafer 10. The seal 8 supports a second substrate, here an IR transparent window 10, here for example, silicon so that with wafer level packaging the window wafer 10 must have compatible thermal expansion coefficient with the FPA wafer which is also silicon. The wafer 10 includes: a plurality of trenches formed in a surface of the wafer 10 to form protrusions 16 having sidewalls to form, here for example, column-like protrusions 16 (FIG. 3b) separated by gaps 18 (FIG. 3a) and getter material members 19 on the sidewalls, shown more clearly in FIG. 5A. The protrusions 16 are preferably rectangular columns for ease of manufacture, but other shapes can also be used. The getter material members 19 may grow as, for example, noodle-like members, rod-like members, cone-shaped members or lumpy globs of getter material. More particularly, the getter material 19 grows on individual sites of the sidewalls of the trenches so that a plurality of getter material members project outwardly from the sidewall of the protrusion.

A detailed perspective view of the IR window 10 is shown in FIG. 3a, which illustrates a preferred embodiment of an etched center portion of the IR window 10 surface facing the detector array (the array portion (i.e., the IR transmissive part of the window) 21, (FIGS. 3a and 5) and the protrusions 16 (i.e., the getter grating portion 23) in another portion of the same surface adjacent the edges of the IR window 10. The width of the trenches is by design narrow enough restrict the arriving angle of the depositing atoms of getter material to a very small angle, typically less than about 3 degrees. A range of the ratio of depth to width may be between about 5 to 1 to 10 or greater to 1. Although it is preferred that the getter grating portion 23 surround the array portion 21 so that the getter traps residual gas molecules inside the Dewar body, the getter portion 23 can be implemented at other locations inside the Dewar body as long as it does not block IR radiation from striking the detector array. Silicon is the preferred material for the second substrate, i.e., the IR window, because it has the same thermal expansion coefficient as the Si FPA wafer. Germanium is more widely used as an IR window in conventional metal or ceramic packages as it has a wide transmittance spectrum with a usable wavelength range of about 2-50 micrometers. However its expansion rate is much higher than Si. Ge could be used in this application if the wafer dimensions were small enough, and bonding temperature was compatible. The surface on which the IR window portion and the getter portion are etched at the same time into the face the substrate and is positioned inside the Dewar assembly when it is sealed.

The column-like protrusions forming the protrusions 16 and the recesses providing the array portion 21 are both preferably etched into the surface of the IR window 10 using a conventional etching method for silicon, and can be etched in a single step or in two separate steps. The getter material 19 (FIG. 5a) is preferably metals deposited by vacuum evaporation onto the surface of the second substrate, i.e., the IR window surface, at a very oblique angle (grazing angle, less than 2 or 3 degrees). The metal atoms will initially nucleate in points on the sidewalls of the column-like protrusions. Further deposition will grow from these points into the depositing direction. As each grain grows, it shadows the area immediately behind it, forcing the growth to form the getter material 19 (FIG. 5a) growing into the direction of the arriving atoms. If the trench structure of the above-described U.S. Pat. No. 5,701,008 is etched into a silicon (Si) lid wafer using very narrow trenches, a getter material from a source 30 (FIG. 5) deposited˜vertically (90 degrees to the plane of the lid wafer 10) will form such getter material 19 on the walls of the protrusions 16, as well as conformally coat the top surface of the protrusions 16. The array portion (IR window) 21 and hermetic seal area 8 are masked during this deposition by a shadow mask, a technique commonly used in the coating industry. The resulting surface area of the deposited getter material will be greater than the geometrical area of the surfaces of the sidewalls of the projections plus the top surface of the protrusions 16. The getter material (i.e., source 30) may be, for example, titanium, which reacts with gas molecules to form metal oxides, carbides, hydrides and nitrides. These compounds are highly stable and relatively permanent at room temperature once they are formed, and therefore the risk of future gas release from these compounds is nearly nonexistent. Species of residual gas molecules that are usually found in an outgassed vacuum-sealed Dewar assembly include oxygen, nitrogen, hydrogen, methane, carbon monoxide and carbon dioxide. An effective getter metal is titanium.

Thus, in summary:

The getter material (an unoxidized metal, such as titanium) is deposited in a way that causes it to form a very non-dense structure with a large surface area (like scales on a butterfly wing).

The metal is preferably vacuum evaporated into narrow trenches between the column-like protrusions 16 etched into the surface of the Wafer Level Package (WLP) cap wafer 10 (i.e., the afore-described second substrate 10) at a grazing angle of incidence with respect to the sidewalls of the protrusions 16 the getter material will nucleate at random points on the sidewalls of the protrusions and subsequent arriving atoms will collect on the nuclei and grow the getter material 19 into the direction of the depositing source 30. Self-shadowing enhances the growth of the getter material 19 growth. The structure will have a greater effective area than the geometric area of the trench. Metal deposited on the wafer surface will have only the geometric area.

The whole Dewar assembly can be fabricated in a vacuum chamber using a conventional process such as that described in U.S. Pat. No. 5,433,639. Contaminants are removed from the substrate and the IR window as well as the solder and getter materials. The substrate and the IR window are then baked in the vacuum chamber at a temperature of about 250 degrees C. to further remove the contaminants.

To fabricate the solder seal, a film of solder is preferably deposited onto narrow metalized strips of the window wafer substrate surface surrounding the getter and window (detector array) areas. The two wafers are then soldered or hybridized together in the vacuum chamber. The Dewar assembly is then cooled and the solder seal solidifies. The hermetically sealed Dewar assembly is thereby produced in the vacuum chamber, and can be removed from the chamber thereafter. It should be understood that the formation of the getter material 19 on the sidewalls of the trenches may also be applied to single Dewar assemblies as well as to wafer level packaging)

A number of embodiments of the disclosure have been described. Nevertheless, it will be understood that various modifications may be made without departing from the spirit and scope of the disclosure. For example, the column-like protrusions may be tapered by the etch chemical and/or crystallographic structure to provide an optimal deposition angle with respect to a deposition at 90 degrees to the wafer surface. Accordingly, other embodiments are within the scope of the following claims.

What is claimed is:

1. A getter structure, comprising:
a substrate having a trench formed in a surface thereof to form a protrusion on the surface;
a plurality getter material members projecting outwardly from a sidewall of the protrusion.

2. The getter structure recited in claim 1 wherein the substrate has a plurality of spaced protrusions and wherein the members extending into gaps between the protrusions.

3. A wafer level vacuum packaged (WLVP) device, comprising:
a first substrate having an array of detectors thereon;
a second substrate bonded to the first substrate, the second substrate having formed thereon:
a trench to provide a protrusion; and
a plurality of getter material members projecting outwardly from a sidewall of the protrusion.

4. The wafer level vacuum packaged (WLVP) device recited in claim 3 wherein the second substrate has a plurality of spaced protrusions and wherein the members have ends extending into gaps between the protrusions.

5. A method for forming a getter structure, comprising:
forming trench in a surface of a substrate to form a protrusion on the surface;
depositing getter material by physical vapor deposition from an evaporating source of the getter material at an oblique angle to the sidewalls, atoms of the getter material initially forming nucleation sites on the sidewalls with subsequent atoms attaching to the nucleation sites and shadowing area surrounding each nucleation site, the getter material thereby growing into a plurality of structures towards the evaporating source.

6. The method recited in claim 5 wherein the substrate has a plurality of spaced protrusions and wherein the members have ends extending into gaps between the protrusions.

7. A getter structure, comprising:
a substrate having a protrusion formed on a surface thereof;
a plurality of getter material members projecting outwardly from a sidewall of the protrusion.

8. The getter structure recited in claim 7 wherein the substrate has a plurality of spaced protrusions and wherein the members have ends extending into gaps between the protrusions.

9. A wafer level vacuum packaged (WLVP) device, comprising:
a first substrate having an array of detectors thereon;
a second substrate bonded to the first substrate, the second substrate having formed thereon:
a protrusion; and
a plurality of getter material members projecting outwardly from a sidewall of the protrusion, such rod-like members being disposed at oblique angles to said sidewall.

10. The wafer level vacuum packaged (WLVP) device recited in claim 9 wherein the second substrate has a plurality of spaced protrusions and wherein the members have ends extending into gaps between the protrusions.

11. A method for forming a getter structure, comprising:
forming a protrusion on a surface of a substrate;
depositing getter material by physical vapor deposition from an evaporating source of the getter material at an oblique angle to the sidewalls, atoms of the getter material initially forming nucleation sites on the sidewalls with subsequent atoms attaching to the nucleation sites and shadowing area surrounding each nucleation site, the getter material thereby growing into structures towards the evaporating source.

12. The method recited in claim 11 wherein the substrate has a plurality of spaced protrusions and wherein the elongated have ends extending into gaps between the protrusions.
